(19) United States
(12) Patent Application Publication
(10) Pub. No.: US 2026/0353954 A1
(43) Pub. Date: Nov. 5, 2026

(54) DISPLAY DEVICE AND ELECTRONIC DEVICE INCLUDING THE SAME

(71) Applicant: Samsung Display Co., Ltd., Yongin-si (KR)

(72) Inventors: Kangmoon Jo, Yongin-si (KR); Kyeuk Lee, Yongin-si (KR); Dooyoung Jung, Yongin-si (KR)

(21) Appl. No.: 19/666,596

(22) Filed: May 4, 2026

(30) Foreign Application Priority Data
May 2, 2025 (KR) 10-2025-0058480

(51) Int. Cl. H10K 59/131; G09G 3/3233; H10K 59/80

(52) U.S. Cl. CPC H10K 59/131; H10K 59/873; G09G 3/3233; G09G 2300/0426; G09G 2300/0819; G09G 2300/0842; G09G 2310/0286; G09G 2310/08

(57) ABSTRACT

A display device comprising: a substrate; a pixel circuit on the substrate in the display area; a transistor portion on the substrate in the circuit arranging area and including a transistor; a plurality of dams in the wiring arranging area, spaced apart from each other in the first direction, and including a first dam in an innermost side; a plurality of wiring portions between the substrate and the plurality of dams, spaced apart from each other, and including a first wiring portion in the innermost side; and an encapsulation layer on the substrate, including an organic encapsulation layer, and covering the display area and the circuit arranging area, wherein the first wiring portion includes: a first wiring part extending in a second direction and in the wiring arranging area; and a second wiring part extending from the first wiring part and having a portion in the circuit arranging area.

### CROSS-REFERENCE TO RELATED APPLICATION

The present application claims priority to and the benefit of Korean Patent Application No. 10-2025-0058480, filed on May 2, 2025, in the Korean Intellectual Property Office, the entire disclosure of which is incorporated herein by reference.

### BACKGROUND

### 1. Field

Aspects of some embodiments of the present disclosure relate to an apparatus, and for example, to a display device and an electronic device.

### 2. Description of the Related Art

Mobile electronic devices are widely used. As mobile electronic devices, recently, table personal computers (PCs) are widely used as well as miniaturized electronic devices such as mobile phones.

To support various functions, for example, to provide a user with visual information, such as images, mobile electronic devices may include a display device. As the parts driving a display device are miniaturized, the proportion of the display device in an electronic device may increase and a structure that may be bent to form a preset angle with respect to a flat state may be utilized.

The above information disclosed in this Background section is only for enhancement of understanding of the background and therefore the information discussed in this Background section does not necessarily constitute prior art.

### SUMMARY

Aspects of some embodiments include a display device, wherein a position of an organic encapsulation layer is relatively easily inspected.

However, such a technical characteristics are examples, and embodiments according to the present disclosure are not limited thereto.

Additional aspects will be set forth in part in the description which follows and, in part, will be apparent from the description, or may be learned by practice of the presented embodiments of the disclosure.

According to one or more embodiments of the present disclosure, a display device including a wiring arranging area, a circuit arranging area, and a display area sequentially arranged in a first direction, includes a substrate, a pixel circuit on the substrate and located in the display area, a transistor portion on the substrate, located in the circuit arranging area, and including at least one transistor, a plurality of dams on the substrate, located in the wiring arranging area, apart from each other in the first direction, and including a first dam in an innermost side, a plurality of wiring portions between the substrate and the plurality of dams in a cross-sectional view, apart from each other in the first direction, and including a first wiring portion in the innermost side, and an encapsulation layer on the substrate, including an organic encapsulation layer, and covering the display area and the circuit arranging area, wherein the first wiring portion includes a first wiring part extending in a second direction crossing the first direction and located in the wiring arranging area, and a second wiring part extending in the first direction from the first wiring part and having at least a portion located in the circuit arranging area.

According to some embodiments, in a plan view, the organic encapsulation layer may overlap the first dam.

According to some embodiments, in a plan view, the first wiring part may be located outside the first dam.

According to some embodiments, in a plan view, the second wiring part may overlap the first dam.

According to some embodiments, in a plan view, an end of the second wiring part may be located inside the first dam.

According to some embodiments, the second wiring part may be provided in plurality.

According to some embodiments, in a plan view, the transistor portion and the second wiring part may be apart from each other.

According to some embodiments, the pixel circuit may include a semiconductor layer, a gate layer overlapping the semiconductor layer, a source electrode electrically connected to a source region of the semiconductor layer, and a drain electrode electrically connected to a drain region of the semiconductor layer, wherein the first wiring portion, the source electrode, and the drain electrode may be on a same layer and may include a same material.

According to some embodiments, the display device may further include a plurality of sub-wiring portions extending in the first direction, located in the wiring arranging area and the circuit arranging area, and electrically connecting the plurality of wiring portions and the transistor portion to each other.

According to some embodiments, in a plan view, the second wiring part may be apart from each of the transistor portion and the plurality of sub-wiring portions.

According to one or more embodiments of the present disclosure, an electronic device including a display device including a wiring arranging area, a circuit arranging area, and a display area sequentially arranged in an inner direction, the electronic device includes a substrate, a pixel circuit on the substrate and located in the display area, a transistor portion on the substrate, located in the circuit arranging area, and including at least one transistor, a plurality of dams on the substrate, located in the wiring arranging area, apart from each other in the inner direction, and including a first dam in an innermost side, a plurality of wiring portions between the substrate and the plurality of dams in a cross-sectional view, apart from each other in the inner direction, and including a first wiring portion in the innermost side, and an encapsulation layer on the substrate, including an organic encapsulation layer, and covering the display area and the circuit arranging area, wherein the first wiring portion includes a first wiring part extending in a circumferential direction of the substrate and located in the wiring arranging area, and a second wiring part extending in the inner direction from the first wiring part and having at least a portion located in the circuit arranging area.

According to some embodiments, in a plan view, the organic encapsulation layer may overlap the first dam.

According to some embodiments, in a plan view, the first wiring part may be outside the first dam.

According to some embodiments, in a plan view, the second wiring part may overlap the first dam.

According to some embodiments, in a plan view, an end of the second wiring part may be inside the first dam.

According to some embodiments, the second wiring part may be provided in plurality.

According to some embodiments, in a plan view, the transistor portion and the second wiring part may be apart from each other.

According to some embodiments, the pixel circuit may include a semiconductor layer, a gate layer on the semiconductor layer, a source electrode electrically connected to a source region of the semiconductor layer, and a drain electrode electrically connected to a drain region of the semiconductor layer, wherein the first wiring portion, the source electrode, and the drain electrode may be on a same layer and may include a same material.

According to some embodiments, the display device may further include a plurality of sub-wiring portions extending in the inner direction, located in the wiring arranging area and the circuit arranging area, and electrically connecting the plurality of wiring portions and the transistor portion to each other.

According to some embodiments, in a plan view, the second wiring part may be apart from each of the transistor portion and the plurality of sub-wiring portions.

Aspects, features, and characteristics other than the above described things will become apparent from the following detailed description of the disclosure, the accompanying drawings, and claims.

### BRIEF DESCRIPTION OF THE DRAWINGS

The above and other aspects, features, and characteristics of certain embodiments of the present disclosure will be more apparent from the following description taken in conjunction with the accompanying drawings, in which:

FIG. 1 is a schematic plan view of a display device according to some embodiments;

FIG. 2 is a schematic conceptual view of a display device according to some embodiments;

FIG. 3 is a block diagram of stages of a scan driver of FIG. 2;

FIG. 4 is a circuit diagram of an N-th stage and an (N+1)-th stage of the scan driver of FIG. 2;

FIG. 5 is a timing diagram of an input signal and a carry signal of an N-th stage and an (N+1)-th stage of the scan driver of FIG. 2;

FIG. 6 is an example of a circuit diagram of some elements for outputting a scan signal SC_N in an N-th stage of the scan driver of FIG. 2;

FIG. 7 is a schematic cross-sectional view of a display device according to some embodiments;

FIG. 8 is a schematic plan view of a display device according to some embodiments;

FIG. 9 is a schematic equivalent circuit diagram of a pixel of the display device of FIG. 1;

FIG. 10 is a block diagram of an electronic device according to some embodiments; and

FIG. 11 is a schematic view of electronic devices according to some embodiments.

### DETAILED DESCRIPTION

Reference will now be made in more detail to aspects of some embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b, and c” indicates only a, only b, only c, both a and b, both a and c, both b and c, all of a, b, and c, or variations thereof.

As the disclosure allows for various changes and numerous embodiments, certain embodiments will be illustrated in the drawings and described in the detailed description. Effects and features of the present disclosure, and methods for achieving them will be clarified with reference to embodiments described below with reference to the drawings. However, the disclosure is not limited to embodiments described below and may be implemented in various forms.

Hereinafter, embodiments of the present disclosure will be described with reference to the accompanying drawings, wherein, like or corresponding elements are given like reference numerals when describing with reference to the drawings, and some repeated description thereof may be omitted.

In embodiments below, such terms as “first” and “second” are not used in a limited meaning and are used for the purpose of distinguishing one element from another.

In embodiments below, the singular expressions include the plural expressions unless the context clearly indicates otherwise.

In embodiments below, the terms such as “comprise” or “have” specify the presence of stated features or elements described in the specification but do not preclude possibility of the addition of one or more other features or elements.

In embodiments below, when a layer, region, or element is referred to as being on another portion, it may include not only a case where the layer, region, or element is directly on the other portion, but also a case where intervening layers, regions, or elements are located therebetween.

Sizes of elements in the drawings may be exaggerated or reduced for convenience of explanation. As an example, the size and thickness of each element shown in the drawings are arbitrarily represented for convenience of description, and thus, the present disclosure is not necessarily limited thereto.

In the embodiments below, an x axis, a y axis and a z axis are not limited to three axes of the rectangular coordinate system, and may be interpreted in a broader sense including the same. For example, the x axis, y axis, and z axis may be perpendicular to one another, or may represent different directions that are not perpendicular to one another.

In the case where a certain embodiment may be implemented differently, a specific process order may be performed in the order different from the described order. As an example, two processes successively described may be simultaneously (or concurrently) performed substantially and performed in the opposite order of the described order.

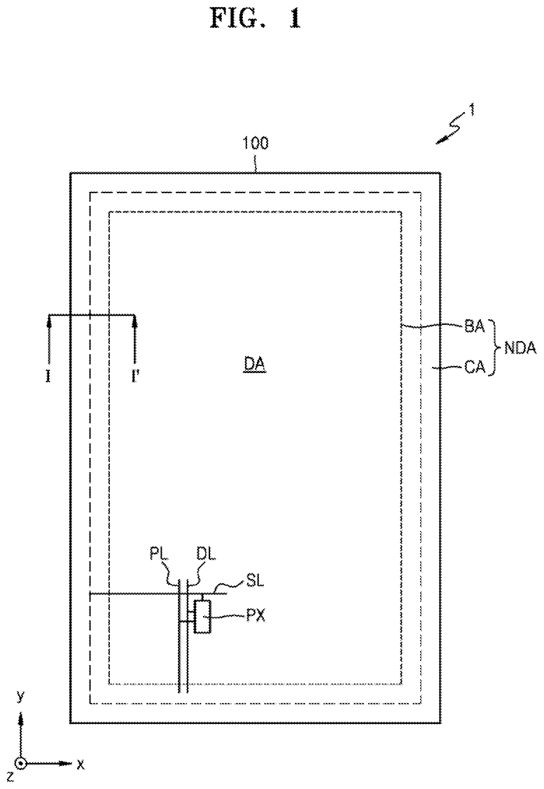

In the present specification, “on a plane” means a plane viewed from a direction perpendicular to a substrate 100 (see FIG. 1). That is, “A and B apart from each other on a plane” means “A and B apart from each other when viewed in a direction perpendicular to the substrate 100 (see FIG. 1).”

In the present specification, “in a cross-section” means a plane cut in a direction perpendicular to the substrate 100 (see FIG. 1). That is, “in a cross-sectional view, A and B apart from each other” means “A and B apart from each other in a plane cut in a direction perpendicular to the substrate 100 (see FIG. 1).”

FIG. 1 is a schematic plan view of a display device 1 according to some embodiments.

Referring to FIG. 1, the display device 1 may include a display panel. As an example, the display device 1 may include various apparatuses such as smartphones, tablet computers, laptop computers, televisions, advertisement boards, or the like. The display device 1 includes thin-film transistors, a capacitor, and the like, and the thin-film transistors, the capacitor, and the like may be implemented by conductive layers and insulating layers.

The display device 1 may include a liquid crystal display panel, an organic light-emitting display panel, or an inorganic light-emitting display panel, and the kind of the display device 1 is not particularly limited. The display device 1 may be a rigid type or a flexible type that is rollable or foldable.

The display device 1 may include a display area DA and a non-display area NDA outside (e.g., surrounding, in a periphery, or outside a footprint of) the display area DA. Although it is shown in FIG. 1 that the display area DA has a rectangular shape, the disclosure is not limited thereto. The display area DA may have various shapes, for example, circular shapes, elliptical shapes, polygonal shapes, or shapes of specific figures.

The display area DA is a region in which images are displayed, and a plurality of pixels PX may be located in the display area DA. Each pixel PX may include a display element such as an organic light-emitting element. Each pixel PX may be configured to emit, for example, red, green, or blue light. The pixel PX may be connected to a pixel circuit including a thin-film transistor TFT, a storage capacitor, and the like. The pixel circuit may be connected to a scan line SL, a data line DL, and a driving voltage line PL, wherein the scan line SL is configured to transfer scan signals, the data line DL crosses the scan line SL and is configured to transfer data signals, and the driving voltage line PL is configured to supply a driving voltage. The data line DL and the driving voltage line PL may extend in a y axis direction (referred to as a first direction, hereinafter), and the scan line SL may extend in an x axis direction (referred to as a second direction, hereinafter).

The pixel PX may be configured to emit light of a brightness corresponding to an electrical signal from the pixel circuit electrically connected thereto. The display area DA may be configured to display preset images by using light emitted from the pixel PX. For reference, the pixel PX may be defined as an emission area that is configured to emit light of one of the colors red, green, and blue.

The non-display area NDA is a region in which pixels PX are not located and may be a region that is configured not to display images. A power supply line for driving the pixel PX and the like may be located in the non-display area NDA. In addition, pads may be located in the non-display area NDA, and a printed circuit board including a driving circuit portion or an integrated circuit element such as a driver integrated circuit (IC), and the pads may be electrically connected to each other in the non-display area NDA.

For reference, because the display device 1 includes the substrate 100, it may be understood that the substrate 100 includes the display area DA and the non-display area NDA. The substrate 100 is described below in more detail.

The non-display area NDA may include a wiring arranging area BA in which a plurality of wiring portions are located, and a circuit arranging area CA in which a transistor portion including at least one transistor is located.

In a plan view, the circuit arranging area CA may be located between the display area DA and the wiring arranging area BA. As an example, the wiring arranging area BA may be arranged along the edge of the display area DA, and arranged along the outer edge of the circuit arranging area CA.

In addition, a plurality of transistors may be located in the display area DA. In the plurality of transistors, depending on the kind (an N type or a P type) of the transistor and/or an operation condition, a first terminal of the transistor may be a source electrode or a drain electrode, and a second terminal may be a different electrode from the first terminal. As an example, in the case where the first terminal is a source electrode, the second terminal may be a drain electrode.

As an example, the plurality of transistors may include a driving transistor, a data-write transistor, a compensation transistor, an initialization transistor, an emission control transistor, and the like. The driving transistor may be connected between the driving voltage line PL and an organic light-emitting element OLED, and the data-write transistor may be connected to the data line DL and the driving transistor and configured to perform a switching operation of transferring a data signal transferred to the data line DL.

The compensation transistor may be turned on according to a scan signal received through the scan line SL and may compensate for the threshold voltage of the driving transistor by connecting the driving transistor and the organic light-emitting element OLED to each other.

The initialization transistor may be turned on according to a scan signal received through the scan line SL and be configured to initialize a gate electrode of the driving transistor by transferring an initialization voltage to the gate electrode of the driving transistor. The scan line connected to the initialization transistor may be a separate scan line from the scan line connected to the compensation transistor.

The emission control transistor may be turned on according to a control signal received through an emission control line, and as a result, a driving current may flow through the organic light-emitting element OLED.

The organic light-emitting element OLED may include a pixel electrode (an anode) and an opposite electrode (a cathode) and receive required voltages from the pixel electrode (the anode) and the opposite electrode (the cathode). The organic light-emitting element may be configured to display images by receiving the driving current from the driving transistor and emitting light.

Hereinafter, although an organic light-emitting display device 1 is described as an example of the display device 1, the display device 1 embodiments according to the present disclosure are not limited thereto. According to some embodiments, the display device 1 of the disclosure may be an inorganic light-emitting display device or a quantum-dot light-emitting display device. As an example, an emission layer of a display element included in the display device 1 may include an organic material or an inorganic material. In addition, the display device 1 may include the emission layer and quantum dots located on a path of light emitted from the emission layer.

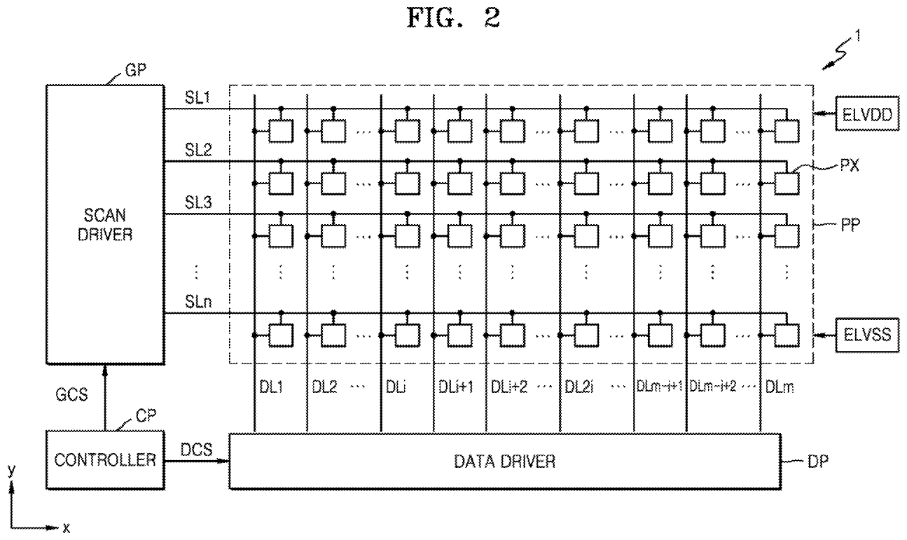

FIG. 2 is a schematic conceptual view of the display device 1 according to some embodiments.

As shown in FIG. 2, the display device 1 may include a pixel portion PP, a scan driver GP, a data driver DP, and a controller CP.

The pixel portion PP in which a plurality of pixels PX are located may be provided in the display area DA. The scan driver GP, the data driver DP, and the controller CP may be provided in the non-display area NDA.

Each of the plurality of pixels PX may be connected to a corresponding scan line among a plurality of scan lines SL1 to SLn, and a corresponding data line among a plurality of data lines DL1 to DLm. Each of the plurality of scan lines SL1 to SLn may extend in the first direction (e.g., the x direction, a row direction) and be connected to pixels PX located in the same row. Each of the scan lines SL1 to SLn may be configured to transfer scan signals to the pixels PX in the same row. Each of the plurality of data lines DL1 to DLm may extend in the second direction (e.g., the y direction, a column direction) and be connected to pixels PX located in the same column.

The scan driver GP may be connected to the plurality of scan lines SL1 to SLn, configured to generate scan signals in response to a gate driving control signal GCS from the controller CP, and sequentially supply the scan signals to the scan lines SL1 to SLn. When scan signals are sequentially supplied to the scan lines SL1 to SLn, the pixels PX may be selected on a row basis. Each of the data lines DL1 to DLm may be configured to transfer data signals DATA to the pixels PX in a selected row. The scan line may be connected to a gate of a transistor included in the pixel PX. A scan signal may be a gate control signal configured to control turning-on and turning-off a transistor connected to the scan line. A scan signal may be a square wave signal in which an on-voltage by which a transistor may be turned on, and an off-voltage by which a transistor may be turned off are repeated.

The scan driver GP may be mounted on the display device 1 as a driving chip. In addition, the scan driver GP may be integrated in the display device 1. As an example, the scan driver GP may include an amorphous silicon thin-film transistor (TFT) gate driver circuit (ASG), a low temperature polycrystalline silicon (LTPS) TFT gate driver circuit, or an oxide semiconductor TFT gate (OSG) driver circuit embedded in the display device 1.

The data driver DP may be configured to convert an image signal into a data signal in the form of a voltage or a current according to a data driving control signal DCS input from the controller CP.

The controller CP may be configured to generate a data driving control signal DCS and a gate driving control signal GCS in response to synchronization signals or a clock signal supplied from the outside. The controller CP may be configured to output a data driving control signal DCS to the data driver DP, and output a gate driving control signal GCS to the scan driver GP.

The scan driver GP may be directly formed on the substrate. The data driver DP may be located on a flexible printed circuit board (FPCB) electrically connected to the pad located on one side of the substrate 100. According to some embodiments, the data driver DP may be directly located on the substrate 100 using a chip-on-glass (COG) method or a chip-on-plastic (COP) method.

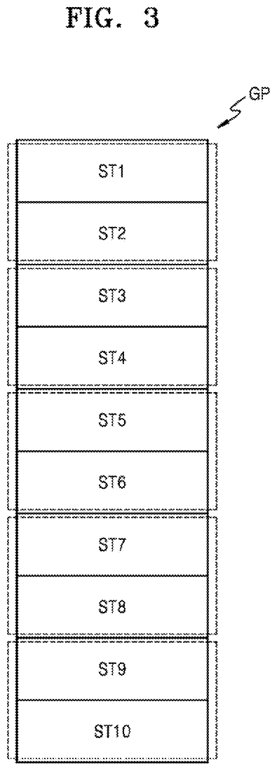

FIG. 3 is a block diagram of stages of the scan driver GP of FIG. 2.

Referring to FIG. 3, the scan driver GP may include a plurality of stages ST1 to ST10. For convenience of description, although ten stages are shown, one stage may output one scan signal, and the number of stages may correspond to the number of gate lines.

Adjacent two stages among the stages may form a stage pair. As an example, a first stage pair may include a first stage ST1 and a second stage ST2. As an example, a second stage pair may include a third stage ST3 and a fourth stage ST4. As an example, a third stage pair may include a fifth stage ST5 and a sixth stage ST6. As an example, a fourth stage pair may include a seventh stage ST7 and an eighth stage ST8. As an example, a fifth stage pair may include a ninth stage ST9 and a tenth stage ST10.

Two stages within the stage pair may include switching elements directly connected to each other. In addition, two stages within the stage pair may share at least one input signal.

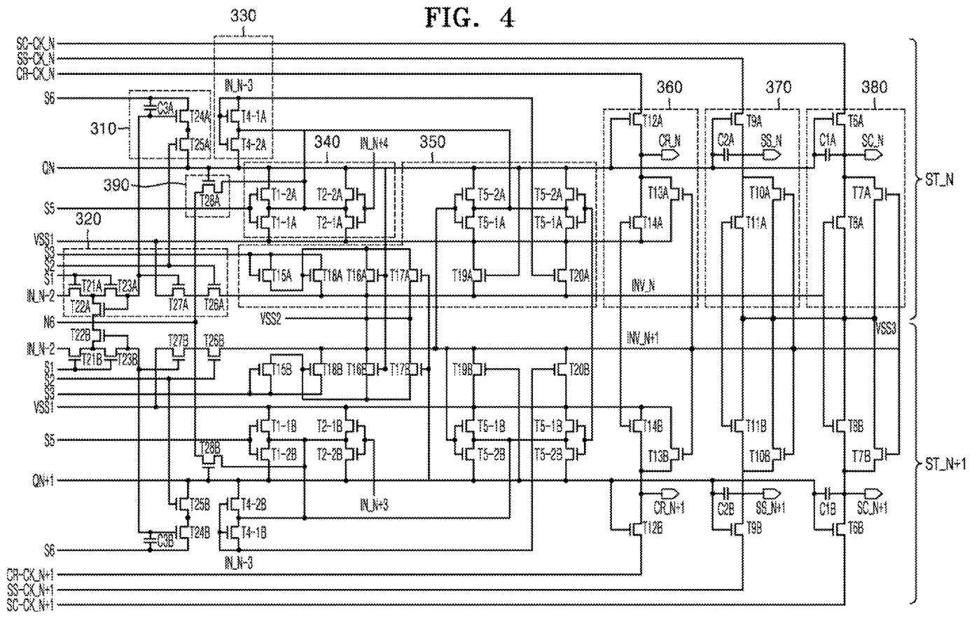

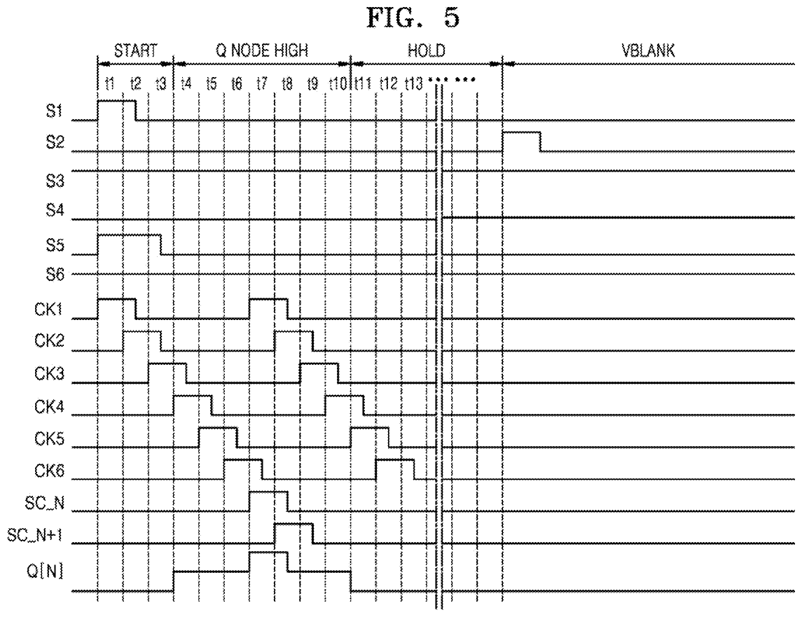

FIG. 4 is a circuit diagram of an N-th stage ST_N and an (N+1)-th stage ST_N+1 of the scan driver of FIG. 2, and FIG. 5 is a timing diagram of an input signal and a carry signal of the N-th stage ST_N and the (N+1)-th stage ST_N+1 of the scan driver of FIG. 2. Although FIG. 4 illustrates various components in stages according to some embodiments, embodiments according to the present disclosure are not limited thereto, and according to various embodiments, the stages may include additional components, or fewer components, without departing from the spirit and scope of embodiments according to the present disclosure.

For reference, the circuit diagram of FIG. 4 is an example for convenience of description, and various circuit diagrams other than FIG. 4 may be used, and the configuration of the transistors for controlling the pixel or controlling scan signals of the scan line may be variously changed depending on the specifications of the display device 1, the request of the user, the environment of the supplier, and the like.

As shown in FIG. 4, the N-th stage ST_N and the (N+1)-th stage ST_N+1 may form a stage pair. The N-th stage ST_N and the (N+1)-th stage ST_N+1 may include switching elements directly connected to each other. In addition, the N-th stage ST_N and the (N+1)-th stage ST_N+1 may share at least one input signal.

First to sixth input signals S1 to S6 may be applied, an N-th clock signal may be applied, and first to third low voltages VSS1, VSS2, and VSS3 may be applied to the N-th stage ST_N. An N-th scan signal SC_N generated from the N-th stage ST_N, and an (N+1)-th scan signal SC_N+1 generated from the (N+1)-th stage ST_N+1 are shown in FIG. 5. For convenience of description, a scan signal mentioned in the present specification may be an N-th scan signal SC_N.

An N-th clock signal may include a gate clock signal SC-CK, a sensing clock signal SS-CK_N, and a carry clock signal CR-CK_N.

As shown in FIG. 4, the N-th stage ST_N may include a first sensor 310, a second sensor 320, a Q-node charger 330, a Q-node stabilizer 340, an inverter 350, a carry signal output unit 360, a sensing signal output unit 370, a scan signal output unit 380, and a switching element stabilizer 390.

The first sensor 310 and the second sensor 320 may operate based on a first input signal S1, a second input signal S2, a sixth input signal S6, and a Q-node signal, and sense the characteristics of a switching element within the pixel PX of the display device 1.

Hereinafter, an example of sensing switching elements mentioned in the present specification may be a transistor or a thin-film transistor located on the substrate.

The first sensor 310 may include a first sensing switching element T24A, a second sensing switching element T25A, and a sensing capacitor C3A.

The sensing capacitor C3A may include a first electrode to which a sixth input signal S6 is applied, and include a second electrode connected to a gate electrode of the first sensing switching element T24A.

The first sensing switching element T24A may include a gate electrode connected to the second electrode of the sensing capacitor C3A, a source electrode to which a sixth input signal S6 is applied, and a drain electrode connected to a source electrode of the second sensing switching element T25A.

The second sensing switching element T25A may include a gate electrode to which a second input signal S2 is applied, a source electrode connected to the drain electrode of the first sensing switching element T24A, and a drain electrode connected to a Q-node QN.

The second sensor 320 may include a third sensing switching element T21A, a fourth sensing switching element T22A, a fifth sensing switching element T23A, a sixth sensing switching element T26A, and a seventh sensing switching element T27A.

The third sensing switching element T21A may include a gate electrode to which a first input signal S1 is applied, a source electrode to which one (e.g., an (N−2)-th carry signal IN_N−2) of previous carry signals is applied, and a drain electrode connected to a source electrode of the fourth sensing switching element T22A.

The fourth sensing switching element T22A may include a gate electrode connected to a drain electrode of the fifth sensing switching element T23A, a source electrode connected to the drain electrode of the third sensing switching element T21A, and a drain electrode connected to a drain electrode of a fourth sensing switching element T22B.

The fifth sensing switching element T23A may include a gate electrode to which a first input signal S1 is applied, a source electrode connected to the drain electrode of the third sensing switching element T21A, and a drain electrode connected to the gate electrode of the fourth sensing switching element T22A.

The sixth sensing switching element T26A may include a gate electrode to which a second input signal S2 is applied, a source electrode connected to the drain electrode of the seventh sensing switching element T27A, and a drain electrode connected to a drain electrode of a tenth inverting switching element T18A.

The seventh sensing switching element T27A may include a gate electrode connected to the drain electrode of the fifth sensing switching element T23A, a source electrode to which the first low voltage VSS1 is applied, and a drain electrode connected to the source electrode of the sixth sensing switching element T26A.

The Q-node charger is configured to charge the Q-node QN based on one of the previous carry signals. Here, one of the previous carry signals may be a carry signal (e.g., an (N−3)-th carry signal IN_N−3) of a current stage to a third previous stage.

The Q-node charger 330 may include a first charging switching element T4-1A and a second charging switching element T4-2A.

The first charging switching element T4-1A may include a gate electrode to which one (e.g., an (N−3)-th carry signal IN_N−3) of the previous carry signals is applied, a source electrode to which one ((N−3)-th carry signal IN_N−3) of the previous carry signals is applied, and a drain electrode connected to a source electrode of the second charging switching element T4-2A.

The second charging switching element T4-2A may include a gate electrode to which one (e.g., an (N−3)-th carry signal IN_N−3) of the previous carry signals is applied, a source electrode connected to a drain electrode of the first charging switching element T4-1A, and a drain electrode connected to the Q-node QN.

The Q-node stabilizer 340 is configured to stabilize the Q-node QN based on one of next carry signals and a fifth input signal S5. Here, one of the next carry signals may be a carry signal (e.g., an (N+4)-th carry signal IN_N+4) of a current stage to a third next stage. As an example, the Q-node stabilizer 340 of a first stage (e.g., an N-th stage ST_N) of a stage pair may receive a carry signal (e.g., an (N+4)-th carry signal IN_N+4) of a current stage to a fourth next stage. As an example, the Q-node stabilizer 340 of a second stage (e.g., an (N+1)-th stage ST_N+1) of a stage pair may receive a carry signal (e.g., an (N+3)-th carry signal IN_N+3) of a current stage to a third next stage. Here, the fifth input signal S5 may be a vertical start signal.

The Q-node stabilizer 340 may include a first stabilization switching element T1-1A, a second stabilization switching element T1-2A, a third stabilization switching element T2-1A, and a fourth stabilization switching element T2-2A.

The first stabilization switching element T1-1A may include a gate electrode to which a fifth input signal S5 is applied, a source electrode connected to a drain electrode of the second stabilization switching element T1-2A, and a drain electrode to which the first low voltage VSS1 is applied.

The second stabilization switching element T1-2A may include a gate electrode to which a fifth input signal S5 is applied, a source electrode connected to the Q-node QN, and the drain electrode connected to the source electrode of the first stabilization switching element T1-1A.

The third charging switching element T2-1A may include a gate electrode to which one (e.g., an (N+4)-th carry signal IN_N+4) of the next carry signals is applied, a source electrode connected to a drain electrode of the fourth stabilization switching element T2-2A, and a drain electrode to which the first low voltage VSS1 is applied.

The fourth stabilization switching element T2-2A may include a gate electrode to which a carry signal (e.g., an (N+4)-th carry signal IN_N+4) of the next carry signals is applied, a source electrode connected to the Q-node QN, and a drain electrode connected to the source electrode of the third stabilization switching element T2-1A.

The inverter 350 may be configured to generate an inverting signal INV_N based on a third input signal S3 and a Q-node signal. The inverter 350 may be configured to also receive a Q-node signal of an (N+1)-th stage ST_N+1 and an inverting signal INV_N+1 of the (N+1)-th stage ST_N+1.

The inverter 350 may include a first inverting switching element T3-1A, a second inverting switching element T3-2A, a third inverting switching element T19A, a fourth inverting switching element T5-1A, a fifth inverting switching element T5-2A, a sixth inverting switching element T20A, a seventh inverting switching element T15A, an eighth inverting switching element T16A, a ninth inverting switching element T17A, and a tenth inverting switching element T18A.

The carry signal output unit 360 may be configured to generate a carry signal CR_N, based on a Q-node signal and inverting signals INV_N and INV_N+1.

The carry signal output unit 360 may include a first carry switching element T12A, a second carry switching element T13A, and a third carry switching element T14A.

The first carry switching element T12A may include a gate electrode connected to the Q-node QN, a source electrode to which a carry clock signal CR-CK_N is applied, and a drain electrode connected to a carry signal output terminal.

The second carry switching element T13A may include a gate electrode to which an inverting signal INV_N+1 of an (N+1)-th stage ST_N+1 is applied, a source electrode connected to a carry signal output terminal, and a drain electrode to which the first low voltage VSS1 is applied.

The third carry switching element T14A may include a gate electrode to which an inverting signal INV_N is applied, a source electrode to which a carry signal CR_N is applied, and a drain electrode to which the first low voltage VSS1 is applied.

The sensing signal output unit 370 may be configured to generate a sensing signal SS_N, based on a Q-node signal and inverting signals INV_N and INV_N+1.

The sensing signal output unit 370 may include a first sensing output switching element T9A, a second sensing output switching element T10A, and a third sensing output switching element T11A.

The first sensing output switching element T9A may include a gate electrode connected to the Q-node QN, a source electrode to which a sensing clock signal SS-CK_N is applied, and a drain electrode connected to a sensing signal output terminal.

The second sensing output switching element T10A may include a gate electrode to which an inverting signal INV_N+1 of an (N+1)-th stage ST_N+1 is applied, a source electrode connected to a sensing signal output terminal, and a drain electrode to which the third low voltage VSS3 is applied.

The third sensing output switching element T11A may include a gate electrode to which an inverting signal INV_N is applied, a source electrode connected to a sensing signal output terminal, and a drain electrode to which the third low voltage VSS3 is applied.

The sensing signal output unit 370 may further include a sensing output capacitor C2A connected between a gate electrode and a drain electrode of the first sensing output switching element T9A.

The scan signal output unit 380 may be configured to generate a scan signal SC_N, based on a Q-node signal and inverting signals INV_N and INV_N+1.

The scan signal output unit 380 may include a first gate switching element T6A, a second gate switching element T7A, and a third gate switching element T8A.

The first gate switching element T6A may include a gate electrode connected to the Q-node QN, a source electrode to which the gate clock signal SC-CK_N is applied, and a drain electrode connected to a scan signal output terminal.

The second gate switching element T7A may include a gate electrode to which an inverting signal INV_N+1 of an (N+1)-th stage ST_N+1 is applied, a source electrode connected to a scan signal output terminal, and a drain electrode to which the third low voltage VSS3 is applied.

The third gate switching element T8A may include a gate electrode to which an inverting signal INV_N is applied, a source electrode connected to a scan signal output terminal, and a drain electrode to which the third low voltage VSS3 is applied.

The scan signal output unit 380 may further include a gate capacitor C1A connected between a gate electrode and a drain electrode of the first gate switching element T6A.

The switching element stabilizer 390 is configured to stabilize an operation of a switching element serially connected thereto by transferring a sixth input signal S6 to an intermediate node of the switching element serially connected thereto in response to the Q-node QN.

The switching element stabilizer 390 may include a switching element stabilizing switching element T28A.

The switching element stabilization switching element T28A may include a gate electrode connected to the Q-node QN, a source electrode to which a sixth input signal S6 is applied, and a drain electrode connected to the drain electrode of the first charging switching element T4-1A. The drain electrode of the switching element stabilization switching element T28A may be commonly connected to a node to which the first charging switching element T4-1A and the second charging switching element T4-2A are connected, a node to which the first stabilization switching element T1-1A and the second stabilization switching element T1-2A are connected, a node to which the third stabilization switching element T2-1A and the fourth stabilization switching element T2-2A are connected, a node to which the first inverting switching element T3-1A and the second inverting switching element T3-2A are connected, and a node to which the fourth inverting switching element T5-1A and the fifth inverting switching element T5-2A are connected.

The N-th stage ST_N and the (N+1)-th stage ST_N+1 shown in FIG. 4 may form a pair, and as shown, the (N+1)-th stage ST_N+1 may include a circuit in a mirrored form with the N-th stage ST_N.

When a third input signal S3 is input to the N-th stage ST_N, a fourth input signal S4 may be applied to a configuration corresponding to the (N+1)-th stage ST_N+1.

In addition, while a carry signal (e.g., an (N+4)-th carry signal IN_N+4) of a current stage (e.g., an N-th stage ST_N) to a fourth next stage is applied to the third stabilization switching element T2-1A and the fourth stabilization switching element T2-2A of a Q-node stabilizer 240 of the N-th stage ST_N, a carry signal (e.g., an (N+3)-th carry signal IN_N+3) of a current stage (e.g., an (N+1)-th stage ST_N+1) to a third next stage is applied to the third stabilization switching element T2-1B and the fourth stabilization switching element T2-2B of a Q-node stabilizer 240 of the (N+1)-th stage ST_N+1.

As shown in FIG. 5, a third input signal S3 may have a high level, and a fourth input signal S4 may have a low level. However, depending on the case, a third input signal S3 and a fourth input signal S4 may be inverted on a frame basis. In the case where a third input signal S3 and a fourth input signal S4 are inverted, a third input signal S3 may have a low level and a fourth input signal S4 may have a high level in the next frame.

Referring to FIGS. 3 and 5, six clock signals CK1 to CK6 having different phases from each other may be sequentially applied to stages of the scan driver GP.

As an example, a first clock signal CK1 may be applied to the first stage ST1, a second clock signal CK2 may be applied to the second stage ST2, a third clock signal CK3 may be applied to the third stage ST3, a fourth clock signal CK4 may be applied to the fourth stage ST4, a fifth clock signal CK5 may be applied to the fifth stage ST5, a sixth clock signal CK6 may be applied to the sixth stage ST6, a first clock signal CK1 may be applied to the seventh stage ST7, a second clock signal CK2 may be applied to the eighth stage ST8, a third clock signal CK3 may be applied to the ninth stage ST9, a fourth clock signal CK4 may be applied to the tenth stage ST10, a fifth clock signal CK5 may be applied to the eleventh stage ST11, and a sixth clock signal CK6 may be applied to the twelfth stage ST12.

Referring to FIG. 5, the N-th stage may be configured to operate based on a first clock signal CK1. First to third horizontal periods t1 to t3 are start sections START, fourth to tenth horizontal periods t4 to t10 are Q-node high sections Q NODE HIGH in which the Q-node QN has a high section, a seventh period t7 is a gate output section in which a scan signal SC_N is output, and an eleventh horizontal period t11 to a vertical blank section VBLANK are holding sections HOLD. From a point at which a second input signal S2 has a high level, the vertical blank section VBLANK starts, and during the vertical blank section VBLANK, the first and second sensors 310 and 320 may be configured to sense the characteristics of a switching element included in the pixel PX.

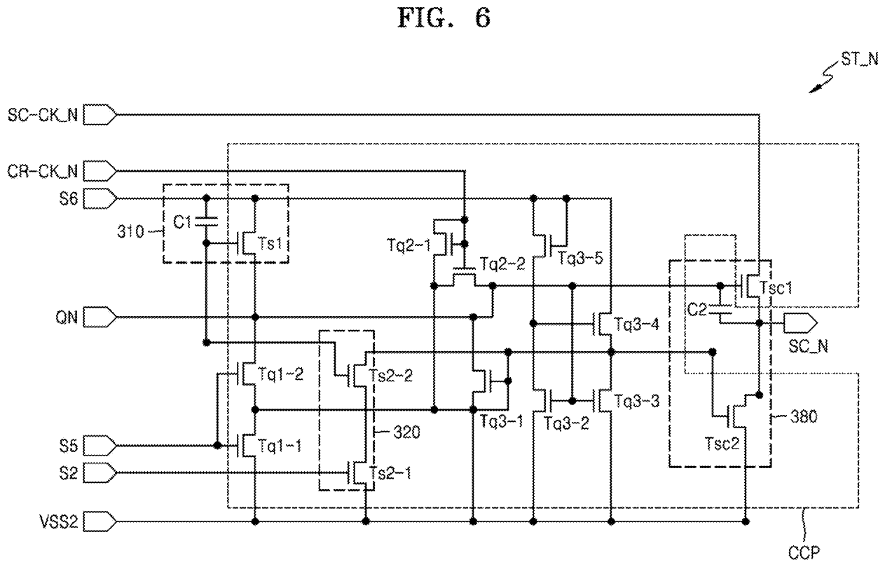

FIG. 6 is an example of a circuit diagram of some elements for outputting a scan signal SC_N in the N-th stage of the scan driver of FIG. 2. Although FIG. 6 illustrates various components in a circuit diagram, embodiments according to the present disclosure are not limited thereto, and according to various embodiments, the circuit may include additional components, or fewer components, without departing from the spirit and scope of embodiments according to the present disclosure.

For reference, the circuit diagram of FIG. 6 is an example for convenience of description, and may be a circuit diagram in which only some elements utilized for outputting a scan signal SC_N are excerpted for convenience of description. In the description of FIG. 6, some description that is identical or overlapping the description of FIGS. 4 and 5 may be omitted.

For reference, elements of the circuit diagram of FIG. 6 may be elements corresponding to elements of the circuit diagram of FIG. 4, and may include some elements different from the elements of the circuit diagram of FIG. 4 or combination of elements. However, the circuit diagram of FIG. 6 is just an example for convenience of description, and the elements of the circuit diagram of FIG. 6 may be variously modified depending on the specifications of the display device 1, the request of the user, the environment of the supplier, and the like.

The circuit of FIG. 6 is a portion of elements configuring the N-th stage ST_N and may include a first capacitor C1, a second capacitor C2, and a transistor portion CCP.

The first capacitor C1 is an element corresponding to the sensing capacitor C3A of FIG. 4, and description of the first capacitor C1 may be replaced with description of the sensing capacitor C3A of FIG. 4.

The second capacitor C2 is an element corresponding to the gate capacitor C1A of FIG. 4, and description of the second capacitor C2 may be replaced with description of the gate capacitor C1A of FIG. 4.

The transistor portion CCP may include elements other than the first capacitor C1 and the second capacitor C2 among the elements of FIG. 6. As an example, the transistor portion CCP may be defined as elements including switching elements (e.g., a thin-film transistor) among some elements for outputting a scan signal SC_N in the N-th stage ST_N of the scan driver GP.

The circuit of FIG. 6 may include the first sensor 310, and the first sensor 310 may include the first capacitor C1 and a first sensing transistor Ts1.

The first sensing transistor Ts1 may be an element corresponding to the first sensing switching element T24A of FIG. 4. Description of the first sensing transistor Ts1 may be replaced with description of the first sensing switching element T24A of FIG. 4.

As an example, a first electrode of the first capacitor C1 may be electrically connected to a terminal that receives a sixth input signal S6. A second electrode of the first capacitor C1 may be electrically connected to a gate electrode of the first sensing transistor Ts1. The terminal that receives a sixth input signal S6 may be electrically connected to a source terminal of the first sensing transistor Ts1.

As an example, the circuit of FIG. 6 may include the second sensor 320, and the second sensor 320 may include a second-1 sensing transistor Ts2-1 electrically connected to a terminal that receives a second input signal S2. A gate electrode of the second-1 sensing transistor Ts2-1 may be electrically connected to the terminal that receives a second input signal S2. A drain electrode of the second-1 sensing transistor Ts2-1 may be electrically connected to a terminal to which the first low voltage VSS1 is applied.

As an example, the second sensor 320 may include a second-2 sensing transistor Ts2-2 electrically connected to the second-1 sensing transistor Ts2-1. A source electrode of the second-1 sensing transistor Ts2-1 may be electrically connected to a drain electrode of the second-2 sensing transistor Ts2-2. A gate electrode of the second-2 sensing transistor Ts2-2 may be electrically connected to a second electrode of the first capacitor C1, and be electrically connected to a gate electrode of the first sensing transistor Ts1.

As an example, the circuit of FIG. 6 may include the scan signal output unit 380, and the scan signal output unit 380 may include the second capacitor C2, a first output transistor Tsc1, and a second output transistor Tsc2.

A first electrode of the second capacitor C2 may be electrically connected to a gate electrode of the first output transistor Tsc1. A first electrode of the second capacitor C2 may be electrically connected to the Q-node QN. A second electrode of the second capacitor C2 may be electrically connected to a drain terminal of the first output transistor Tsc1. A drain terminal of the first output transistor Tsc1 may be electrically connected to also an output terminal from which a scan signal SC_N is output. The drain terminal of the first output transistor Tsc1 may be electrically connected to also a source terminal of the second output transistor Tsc2. A drain terminal of the second output transistor Tsc2 may be electrically connected to a terminal to which the first low voltage VSS1 is transferred. As an example, the first low voltage VSS1 may be a ground voltage. Depending on the case, the first low voltage VSS1 may be replaced with the second low voltage VSS2.

The circuit of FIG. 6 may further include a plurality of switching elements (transistors). As an example, the circuit of FIG. 6 may further include a first-1 node transistor Tq1-1 to a third-5 node transistor Tq3-5. The circuit of FIG. 6 may include node transistors corresponding to switching elements included in the Q-node charger 330 and the Q-node stabilizer 340 of FIG. 4.

As an example, a terminal that transfers a fifth input signal S5 may be electrically connected to a gate electrode of the first-1 node transistor Tq1-1 and a gate electrode of the first-2 node transistor Tq1-2. A drain electrode of the first-1 node transistor Tq1-1 may be electrically connected to a terminal to which the second low voltage VSS2 is transferred, and a source electrode of the first-1 node transistor Tq1-1 may be electrically connected to a drain electrode of the first-2 node transistor Tq1-2. A source electrode of the first-2 node transistor Tq1-2 may be electrically connected to the Q-node QN. As an example, the first-1 node transistor Tq1-1 and the first-2 node transistor Tq1-2 may correspond to switching elements included in the Q-node stabilizer 340 of FIG. 4.

As an example, a second-1 node transistor Tq2-1 may be electrically connected to a second-2 node transistor Tq2-2, and a source electrode and a gate electrode of the second-1 node transistor Tq2-1 may be electrically connected to a terminal to which a carry clock signal CR-CK_N is transferred. The gate electrode of the second-1 node transistor Tq2-1 may be electrically connected to a gate electrode of the second-2 node transistor Tq2-2. A drain electrode of the second-1 node transistor Tq2-1 may be electrically connected to a source electrode of the second-2 node transistor Tq2-2. As an example, the second-1 node transistor Tq2-1 and the second-2 node transistor Tq2-2 may correspond to switching elements included in the Q-node stabilizer 340 of FIG. 4.

As an example, a third-1 node transistor Tq3-1 may be electrically connected to the Q-node QN. A source electrode of the third-1 node transistor Tq3-1 may be electrically connected to the Q-node QN, and a gate electrode of the third-1 node transistor Tq3-1 may be electrically connected to a source terminal of the second-2 sensing transistor. A drain electrode of the third-1 sensing transistor Tq3-1 may be electrically connected to a terminal to which the second low voltage VSS2 is transferred.

As an example, a third-2 node transistor Tq3-2 may be electrically connected to the Q-node QN. A source electrode of the third-2 node transistor Tq3-2 may be electrically connected to a drain electrode of a third-5 node transistor Tq3-5, and a drain electrode of the third-2 node transistor Tq3-2 may be electrically connected to a terminal to which the second low voltage VSS2 is transferred. A gate electrode of the third-2 node transistor Tq3-2 may be electrically connected to a third-3 node transistor Tq3-3 and the Q-node QN.

As an example, the third-3 node transistor Tq3-3 may be electrically connected to the Q-node QN, the third-2 node transistor Tq3-2, and a third-4 node transistor Tq3-4. A source electrode of the third-3 node transistor Tq3-3 may be electrically connected to a drain electrode of the third-4 node transistor Tq3-4, and a gate electrode of the third-3 node transistor Tq3-3 may be electrically connected to the gate electrode of the third-2 node transistor Tq3-2 and the Q node QN.

As an example, the third-4 node transistor Tq3-4 may be electrically connected to the third-2 node transistor Tq3-2, the third-3 node transistor Tq3-3, and the third-5 node transistor Tq3-5. A source electrode of the third-4 node transistor Tq3-4 may be electrically connected to a source electrode of the third-5 node transistor Tq3-5 and a gate electrode of the third-5 node transistor Tq3-5. A source electrode of the third-4 node transistor Tq3-4 may be electrically connected to a terminal to which a sixth input signal S6 is transferred. A gate electrode of the third-4 node transistor Tq3-4 may be electrically connected to a drain electrode of the third-5 node transistor Tq3-5 and a source electrode of the third-2 node transistor Tq3-2. A drain electrode of the third-4 node transistor Tq3-4 may be electrically connected to a source electrode of the third-3 node transistor Tq3-3.

As an example, the third-5 node transistor Tq3-5 may be electrically connected to a terminal to which a sixth input signal S6 is transferred, the third-2 node transistor Tq3-2, and the third-4 node transistor Tq3-4. A source electrode of the third-5 node transistor Tq3-5 may be electrically connected to a gate electrode of the third-5 node transistor Tq3-5, and be electrically connected to a source electrode of the third-4 node transistor Tq3-4. A drain electrode of the third-5 node transistor Tq3-5 may be electrically connected to a gate electrode of the third-4 node transistor Tq3-4 and a source electrode of the third-2 node transistor Tq3-2.

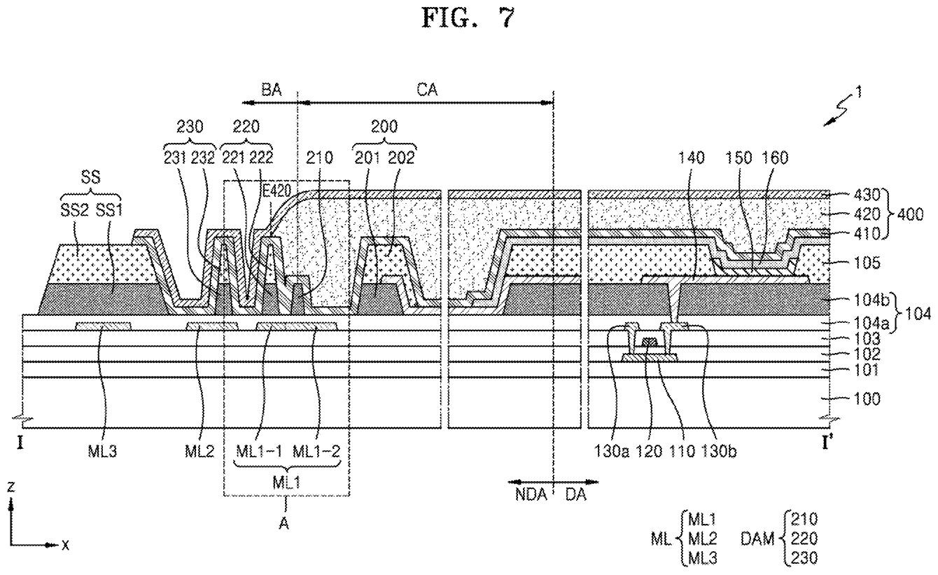

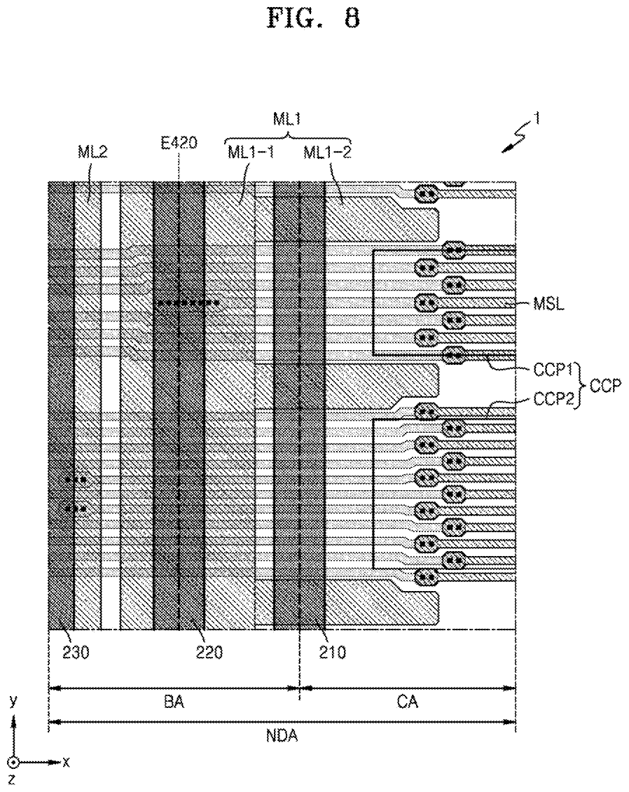

FIG. 7 is a schematic cross-sectional view of the display device 1 according to some embodiments, and FIG. 8 is a schematic plan view of the display device 1 according to some embodiments.

For example, FIG. 7 is a cross-sectional view of the display device 1 taken along the line I-I′ of FIG. 1, and FIG. 8 is a plan view of a region A of FIG. 7.

Referring to FIGS. 7 and 8, the display device 1 may include the display area DA and the non-display area NDA. In addition, the non-display area NDA may include the circuit arranging area CA and the wiring arranging area BA.

As described above with reference to FIG. 1, the wiring arranging area BA, the circuit arranging area CA, and the display area DA may be sequentially arranged in the inner direction of the substrate 100. FIGS. 7 and 8 show a partial region of the display device 1, and the wiring arranging area BA, the circuit arranging area CA, and the display area DA may be arranged in the first direction (e.g., the x axis direction).

The substrate 100 may include the display area DA and regions corresponding to the non-display area NDA outside the display area DA. The substrate 100 may include various flexible or bendable materials. As an example, the substrate 100 may include glass, metal, or a polymer resin. In addition, the substrate 100 may include polymer resin such as polyethersulphone, polyacrylate, polyetherimide, polyethylene naphthalate, polyethylene terephthalate, polyphenylene sulfide, polyarylate, polyimide, polycarbonate, or cellulose acetate propionate. The substrate 100 may have a multi-layered structure including two layers each including the polymer resin, and a barrier layer including an inorganic material (such as silicon oxide, silicon nitride, and silicon oxynitride) therebetween. However, various modifications may be made.

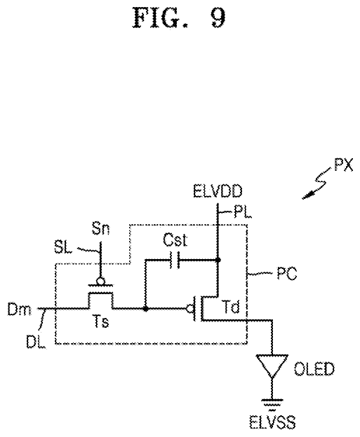

A pixel circuit PC (see FIG. 9) may be located on the substrate 100. The pixel circuit PC (see FIG. 9) may be located in the display area DA. The pixel circuit PC (see FIG. 9) may include a semiconductor layer 110, a gate layer 120, a source electrode 130a, and a drain electrode 130b.

A buffer layer 101 may be located on the substrate 100. The buffer layer 101 may be configured to prevent or reduce impurity ions diffusing, prevent or reduce penetration of contaminants such as moisture or external air, and may serve as a barrier layer for planarizing a surface, and/or a blocking layer. The buffer layer 101 may include silicon oxide, silicon nitride, or silicon oxynitride. In addition, the buffer layer 101 may allow the semiconductor layer 110 to be uniformly crystallized by adjusting the providing speed of heat during a crystallization process for forming the semiconductor layer 110.

The semiconductor layer 110 may be located on the buffer layer 101. The semiconductor layer 110 may include polycrystalline silicon and include a channel region not doped with impurities, a source region, and a drain region on two opposite side of the channel region, the source region and the drain region being doped with impurities. Here, the impurities may change depending on the kind of a thin-film transistor and be N-type impurities or P-type impurities. According to some embodiments, the display device according to the disclosure may further include another semiconductor layer located on a different layer.

A gate insulating layer 102 may be located on the semiconductor layer 110. The gate insulating layer 102 may be a configuration for securing insulation between the semiconductor layer 110 and the gate layer 120. The gate insulating layer 102 may include an inorganic material such as silicon oxide, silicon nitride, and/or silicon oxynitride, and be located between the semiconductor layer 110 and the gate layer 120. In addition, the gate insulating layer 102 has a shape corresponding to the entire surface of the substrate 100 and may have a structure in which contact holes are formed in preset portions thereof. Like this, the insulating layer including the inorganic material may be formed by chemical vapor deposition (CVD) or atomic layer deposition (ALD). This is also applicable to embodiments below and modifications thereof.

The gate layer 120 may be located on the gate insulating layer 102. The gate layer 120 may be located at a position vertically overlapping the semiconductor layer 110. The gate layer 120 may include at least one of molybdenum (Mo), aluminum (Al), platinum (Pt), palladium (Pd), silver (Ag), magnesium (Mg), gold (Au), nickel (Ni), neodymium (Nd), iridium (Ir), chromium (Cr), lithium(Li), calcium (Ca), titanium (Ti), tungsten (W), or copper (Cu). The gate layer 120 is described below in more detail. According to some embodiments, the display device according to the disclosure may further include another gate layer located on a different layer.

An interlayer insulating layer 103 may be located on the gate layer 120. The interlayer insulating layer 103 may cover the gate layer 120. The interlayer insulating layer 103 may include an inorganic material. As an example, the interlayer insulating layer 103 may be a metal oxide or a metal nitride, and for example, the inorganic material may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO₂). According to some embodiments, the interlayer insulating layer 103 may include a double structure of SiOₓ/SiN_{y} or SiNₓ/SiO_{y}.

A source electrode 130a and a drain electrode 130b may be located on the interlayer insulating layer 103. The source electrode 130a and the drain electrode 130b may serve as electrodes connected to source/drain regions of the semiconductor layer 110 via through holes included in the interlayer insulating layer 103.

The source electrode 130a and the drain electrode 130b may include at least one of aluminum (Al), platinum (Pt), palladium (Pd), silver (Ag), magnesium (Mg), gold (Au), nickel (Ni), neodymium (Nd) , iridium (Ir), chromium (Cr), lithium (Li), calcium (Ca), molybdenum (Mo), titanium (Ti), tungsten (W), or copper (Cu). As an example, the source electrode 130a and the drain electrode 130b may include a Ti layer, an Al layer, and/or a Cu layer. As an example, the source electrode 130a and the drain electrode 130b may include a structure of Ti/Al/Ti.

An inorganic protective layer may cover the source electrode 130a and the drain electrode 130b. The inorganic protective layer may be a single layer or a multi-layer of silicon nitride (SiNₓ) and silicon oxide (SiOₓ).

A first organic insulating layer 104a may be located on the source electrode 130a and the drain electrode 130b. The first organic insulating layer 104a may cover the upper portion of the source electrode 130a and the drain electrode 130b, and be an organic insulating layer having a generally flat upper surface and serving as a planarization layer. The first organic insulating layer 104a may include an organic material, for example, acryl, benzocyclobutene (BCB), or hexamethyldisiloxane (HMDSO). The first organic insulating layer 104a may include a single layer or a multi-layer. However, various modifications may be made.

A second organic insulating layer 104b may be located on the first organic insulating layer 104a. The second organic insulating layer 104b may include an organic material, for example, acryl, benzocyclobutene (BCB), or hexamethyldisiloxane (HMDSO). The second organic insulating layer 104b may include a single layer or a multi-layer. However, various modifications may be made.

A pixel electrode 140 may be located on the second organic insulating layer 104b. In the display area DA, the pixel electrode 140 may be connected to the source electrode 130a and/or the drain electrode 130b through a contact hole formed in the first organic insulating layer 104a and the second organic insulating layer 104b. In the display area DA, a display element may be located on the pixel electrode 140. As a display element, an organic light-emitting element may be used. That is, the organic light-emitting element may be located on, for example, the pixel electrode 140. The pixel electrode 140 may include a light-transmissive conductive layer and/or a reflective layer, wherein the light-transmissive conductive layer includes a light-transmissive conductive oxide such as indium tin oxide (ITO), indium oxide (In₂O₃), or indium zinc oxide (IZO), and the reflective layer includes metal such as aluminum (Al) or silver (Ag). As an example, the pixel electrode 140 may have a three-layered structure of ITO/Ag/ITO.

A pixel-defining layer 105 may be located on the second organic insulating layer 104b and arranged to cover the edge of the pixel electrode 140. As an example, the pixel-defining layer 105 may cover the edge of the pixel electrode 140. The pixel-defining layer 105 has an opening corresponding to the pixel, and the opening may be formed to expose at least the central portion of the pixel electrode 140. The opening may be defined by the pixel-defining layer 105.

The pixel-defining layer 105 may include, for example, an organic material such as polyimide or HMDSO. In addition, a spacer may be located on the pixel-defining layer 105. Although it is shown that the spacer is located in the non-display area NDA, the spacer may be located in the display area DA. The spacer may prevent or reduce damage to the organic light-emitting element by sagging of a mask during the manufacturing process that uses the mask. The spacer may include an organic insulating material and include a single layer or a multi-layer.

An intermediate layer 150 and an opposite electrode 160 may be located on the opening. The intermediate layer 150 may include a low-molecular weight material or a polymer material, and in the case where the intermediate layer 150 includes a low-molecular weight material, the intermediate layer 150 may include a hole injection layer, a hole transport layer, an emission layer, an electron transport layer, and/or an electron injection layer. In the case where the intermediate layer 150 includes a polymer material, the intermediate layer 150 may have a structure including the hole transport layer and the emission layer.

The structure of the intermediate layer 150 is not limited thereto and may be various structures. As an example, at least one of layers forming the intermediate layer 150 may be integrally formed like the opposite electrode 160. According to some embodiments, the intermediate layer 150 may have a layer patterned to correspond to each of the plurality of pixel electrodes 140.

The opposite electrode 160 may include a light-transmissive conductive layer including a light-transmissive conductive oxide such as ITO, In₂O₃, or IZO. The pixel electrode 140 may be used as an anode, and the opposite electrode 160 may be used as a cathode. The polarity of the electrodes may also be reversed.

The opposite electrode 160 is located on the upper portion of the display area DA and may be arranged in the entire surface of the display area DA. That is, the opposite electrode 160 may be integrally formed to cover the plurality of pixels. The opposite electrode 160 may be in electrical contact with a common power line located in the non-display area NDA. As an example, the opposite electrode 160 may extend up to a partition wall 200 described below.

An encapsulation layer 400 may be located on the substrate 100. The encapsulation layer 400 may cover the display area DA entirely, extend to the non-display area NDA, and be arranged to cover at least a portion of the non-display area NDA. For example, the encapsulation layer 400 may cover the display area DA and the circuit arranging area CA entirely, and cover a portion of the wiring arranging area BA. The encapsulation layer 400 may extend up to the outside of the partition wall 200.

The encapsulation layer 400 may include a first inorganic encapsulation layer 410, a second inorganic encapsulation layer 430, and an organic encapsulation layer 420 therebetween. The first and second inorganic encapsulation layers 410 and 430 may include at least one inorganic material among aluminum oxide, titanium oxide, tantalum oxide, hafnium oxide, zinc oxide, silicon oxide, silicon nitride, silicon oxynitride, and the like. The first and second inorganic encapsulation layers 410 and 430 may include a single layer or a multi-layer including the above materials. The first and second inorganic encapsulation layers 410 and 430 may include the same material or include different materials from each other.

The thickness of the first inorganic encapsulation layer 410 may be different from that of the second inorganic encapsulation layer 430. The thickness of the first inorganic encapsulation layer 410 may be greater than that of the second inorganic encapsulation layer 430. Alternatively, the thickness of the second inorganic encapsulation layer 430 may be greater than that of the first inorganic encapsulation layer 410, or the thickness of the first inorganic encapsulation layer 410 may be the same as that of the second inorganic encapsulation layer 430.

The organic encapsulation layer 420 may include a monomer-based material or a polymer-based material. The polymer-based material may include an acryl-based resin, an epoxy-based resin, polyimide, and polyethylene. As an example, the organic encapsulation layer 420 may include acrylate.

The partition wall 200 may be located in the non-display area NDA. For example, the partition wall 200 may be located in the circuit arranging area CA. As an example, although the partition wall 200 may include a portion 221 of the organic insulating layer 104 and a portion 212 of the pixel-defining layer 105, the disclosure is not necessarily limited thereto. As an example, a lower layer of the partition wall 200 may be the portion 221 of the organic insulating layer 104, and an upper layer of the partition wall 200 may be the portion 212 of the pixel-defining layer 105.

Depending on the case, the partition wall 200 may further include a portion of the spacer, and the portion of the spacer may be located on the portion 212 of the pixel-defining layer 105, and the portion 212 of the pixel-defining layer 105 may be located on the portion 221 of the organic insulating layer 104. The partition wall 200 may be arranged to surround the display area DA, and may prevent or reduce the organic encapsulation layer 420 of the encapsulation layer 400 overflowing to the outside of the substrate 100.

A plurality of dams DM may be located in the non-display area NDA. The plurality of dams DAM may prevent or reduce an edge tail of the organic encapsulation layer 420 being formed by blocking an organic material from flowing in the edge direction of the substrate 100 when forming the organic encapsulation layer 420. The plurality of dams DAM may be located in the non-display area NDA to surround (e.g., in a periphery or outside a footprint of) at least a portion of the display area DA. For example, the plurality of dams DAM may be located in the wiring arranging area BA.

Although it is shown in FIG. 7 that three dams DAM are provided, this is just an example and the number of the plurality of dams DAM is not limited thereto. As an example, two dams DAM may be provided, or four or more dams DAM may be provided. Hereinafter, description is made on the assumption that three dams DAM are provided.

The plurality of dams DAM may include a first dam 210, a second dam 220, and a third dam 230. The first dam 210, the second dam 220, and the third dam 230 may be apart from each other in an inner direction. The first dam 210, the second dam 220, and the third dam 230 may be apart from each other in the first direction (e.g., the x axis direction). The second dam 220 may be arranged to surround at least a portion of the first dam 210. The third dam 230 may be arranged to surround at least a portion of the second dam 220. The first dam 210 may be arranged in an innermost side among the plurality of dams DAM, and the third dam 230 may be arranged in an outermost side among the plurality of dams DAM.

As an example, in a plan view, the organic encapsulation layer 420 may overlap the first dam 210. As an example, an end E420 of the organic encapsulation layer 420 may be located on the second dam 220. However, this is just an example, and unlike FIGS. 7 and 8, the end E420 of the organic encapsulation layer 420 may be located between the second dam 220 and the third dam 230.

The plurality of dams DAM may have various layered structures. As an example, the first dam 210 may have a single-layered structure. As an example, the second dam 220 and the third dam 230 may have a multi-layered structure.

The plurality of dams DAM and the partition wall 200 may be located on the substrate 100. A lower layer 201 of the partition wall 200, a lower layer 221 of the second dam 220, and a lower layer 231 of the third dam 230 may include, for example, the same material as the organic insulating layer 104 and be located on the same layer as the organic insulating layer 104. The lower layer 201 of the partition wall 200, the lower layer 221 of the second dam 220, and the lower layer 231 of the third dam 230 may have, for example, the same layered structure as the organic insulating layer 104. The lower layer 201 of the partition wall 200, the lower layer 221 of the second dam 220, and the lower layer 231 of the third dam 230 may be simultaneously (or concurrently) formed during, for example, the same process as a process of forming the organic insulating layer 104.

An upper layer 202 of the partition wall 200, an upper layer 222 of the second dam 220, and an upper layer 232 of the third dam 230 may include, for example, the same material as the pixel-defining layer 105 and be located on the same layer as the pixel-defining layer 105. The upper layer 202 of the partition wall 200, the upper layer 222 of the second dam 220, and the upper layer 232 of the third dam 230 may have, for example, the same layered structure as the pixel-defining layer 105. The upper layer 202 of the partition wall 200, the upper layer 222 of the second dam 220, and the upper layer 232 of the third dam 230 may be simultaneously (or concurrently) formed during, for example, the same process as a process of forming the pixel-defining layer 105.

It is shown as an example in FIG. 7 that the first dam 210 has a single-layered structure. The lower layer 201 of the first dam 210 and the partition wall 200 may include, for example, the same material as the organic insulating layer 104 and be located on the same layer as the organic insulating layer 104. The lower layer 201 of the first dam 210 and the partition wall 200 may have, for example, the same layered structure as the organic insulating layer 104. The lower layer 201 of the first dam 210 and the partition wall 200 may be simultaneously (or concurrently) formed during, for example, the same process as a process of forming the organic insulating layer 104.

A plurality of wiring portions ML may be located in the non-display area NDA. The plurality of wiring portions ML may be located between the substrate 100 and the plurality of dams DAM in a cross-sectional view. The plurality of wiring portions ML may be located on the interlayer insulating layer 103. As an example, first to sixth input signals S1 to S6 (see FIGS. 4 to 6) may be transferred to the plurality of wiring portions ML. As an example, first to sixth clock signals CK1, CK2, CK3, CK4, CK5, and CK6 (see FIGS. 4 to 6) may be transferred to the plurality of wiring portions ML. As an example, an N-th scan signal SC_N (see FIGS. 4 to 6) and an (N+1)-th scan signal SC-N+1 (see FIGS. 4 to 6) may be transferred to the plurality of wiring portions ML. As an example, the first to third low voltages VSS1, VSS2, and VSS3 (see FIGS. 4 to 6) may be transferred to the plurality of wiring portions ML.

The above inorganic protective layer may cover the plurality of wiring portions ML. The first organic insulating layer 104a may be located on the plurality of wiring portions ML. The first organic insulating layer 104a may cover the upper portion of the plurality of wiring portions ML, and be an organic insulating layer having a generally flat upper surface and serving as a planarization layer.

Although it is shown in FIG. 7 that three wiring portions ML are provided, this is just an example and the number of the plurality of wiring portions ML is not limited thereto. As an example, two wiring portions ML may be provided, or four or more wiring portions ML may be provided. Hereinafter, description is made on the assumption that three wiring portions ML are provided.

The plurality of wiring portions ML may include a first wiring portion ML1, a second wiring portion ML2, and a third wiring portion ML3. The first wiring portion ML1, the second wiring portion ML2, and the third wiring portion ML3 may be apart from each other in an inner direction. As an example, the first wiring portion ML1, the second wiring portion ML2, and the third wiring portion ML3 may be apart from each other in the first direction (e.g., the x axis direction). The second wiring portion ML2 may be arranged to surround at least a portion of the first wiring portion ML1. The third wiring portion ML3 may be arranged to surround at least a portion of the second wiring portion ML2. The first wiring portion ML1 may be located in an innermost side of the plurality of wiring portions ML, and the third wiring portion ML3 may be located in an outermost side of the plurality of wiring portions ML.

The plurality of wiring portions ML may include the same material as the source electrode 130a and the drain electrode 130b and be located on the same layer as the source electrode 130a and the drain electrode 130b. As an example, the first wiring portion ML1, the second wiring portion ML2, and the third wiring portion ML3 may include the same material as the source electrode 130a and the drain electrode 130b and be located on the same layer as the source electrode 130a and the drain electrode 130b.

The plurality of wiring portions ML may include at least one of aluminum (Al), platinum (Pt), palladium (Pd), silver (Ag), magnesium (Mg), gold (Au), nickel (Ni), neodymium (Nd) , iridium (Ir), chromium (Cr), lithium (Li), calcium (Ca), molybdenum (Mo), titanium (Ti), tungsten (W), or copper (Cu). As an example, the plurality of wiring portions ML may include a Ti layer, an Al layer, and/or a Cu layer. As an example, the plurality of wiring portions ML may include a structure of Ti/Al/Ti.

The first wiring portion ML1 may include a first wiring part ML1-1 and a second wiring part ML1-2. The first wiring part ML1-1 may extend in a circumferential direction of the substrate 100. As an example, the first wiring part ML1-1 may extend in the second direction (e.g., the y axis direction). The first wiring part ML1-1 may be located in the wiring arranging area BA. In a plan view, the first wiring part ML1-1 may be located outside the first dam 210.

The second wiring part ML1-2 may extend in an inner direction from the first wiring part ML1-1. As an example, the second wiring part ML1-2 may extend in the first direction (e.g., the x axis direction) from the first wiring part ML1-1. At least a portion of the second wiring part ML1-2 may be located in the circuit arranging area CA. In a plan view, the second wiring part ML1-2 may overlap the first dam 210. In a plan view, an end of the second wiring part ML1-2 may be located inside the first dam 210. As an example, the second wiring part ML1-2 may be provided in plurality. The plurality of the second wiring parts ML1-2 may be apart from each other in the second direction (e.g., the y axis direction).

The plurality of wiring portions ML other than the first wiring portion ML1 may extend in the second direction (e.g., the y axis direction). As an example, the second wiring portion ML2 and the third wiring portion ML3 may extend in the second direction (e.g., the y axis direction). The plurality of wiring portions other than the first wiring portion ML1 may be located in the wiring arranging area BA. As an example, the second wiring portion ML2 and the third wiring portion ML3 may be located in the wiring arranging area BA.

A region to which the organic encapsulation layer 420 is located may be inspected by irradiating light on the encapsulation layer 400. For example, on the encapsulation layer 400, light may be irradiated to the second wiring part ML1-2 including an opaque material. The second wiring part ML1-2 located inside the first dam 210 may reflect light back to the outside. A difference in reflectivity may appear between a case where the organic encapsulation layer 420 is located on the second wiring part ML1-2 located inside the first dam 210 and a case where the organic encapsulation layer 420 is not located on the second wiring part ML1-2. Whether the organic encapsulation layer 420 is located on the second wiring part ML1-2 located inside the first dam 210 may be determined by using the difference in the reflectivity.

As the display device 1 becomes higher in resolution, the circuit arranging area CA in the non-display area NDA may become wider and the wiring arranging area BA may become narrower. However, even though the wiring arranging area BA becomes narrower, because at least a portion of the second wiring part ML1-2 of the first wiring portion ML1 is located in the circuit arranging area CA, whether the end of the organic encapsulation layer 420 overlaps the first dam 210 or is located outside the first dam 210 may be determined.

According to some embodiments, as shown in FIG. 8, the display device 1 may include the transistor portion CCP and a plurality of sub-wiring portions MSL.

The transistor portion CCP may be located on the substrate 100. The transistor portion CCP may include at least one transistor. At least one transistor included in the transistor portion CCP may configure a circuit required for the scan driver GP (see FIG. 3). The transistor portion CCP may be located in the circuit arranging area CA. In a plan view, the transistor portion CCP may be apart from the wiring arranging area BA.

Although an example of at least one transistor configuring the transistor portion CCP may be arranged according to the circuit diagram of FIG. 4 or the circuit diagram of FIG. 6 described above, this is just an example for understanding, and embodiments according to the present disclosure are not limited thereto.

The transistor portion CCP may be provided in plurality. As an example, the transistor portion CCP may include a first transistor portion CCP1 and a second transistor portion CCP2. The first transistor portion CCP1 and the second transistor portion CCP2 may be apart from each other in the second direction (e.g., the y axis direction). As an example, the first transistor portion CCP1 may correspond to the N-th stage ST_N (see FIG. 4), and the second transistor portion CCP2 may correspond to the (N+1)-th stage ST_N+1 (see FIG. 4).

The plurality of sub-wiring portions MSL may extend in the first direction (e.g., the x axis direction). The plurality of sub-wiring portions MSL may be located in the wiring arranging area BA and the circuit arranging area CA. The plurality of sub-wiring portions MSL may electrically connect the plurality of wirings ML and the transistor portion CCP to each other. As an example, the plurality of sub-wiring portions MSL may electrically connect each of the first wiring portion ML1, the second wiring portion ML2, and the third wiring portion ML3 to the first transistor portion CCP1 and the second transistor portion CCP2.

In a plan view, the plurality of sub-wiring portions MSL and the transistor portion CCP may overlap each other in the circuit arranging area CA. In a plan view, the transistor portion CCP and the second wiring part ML1-2 may be apart from each other. In a plan view, the plurality of sub-wiring portions MSL and the second wiring part ML1-2 may be apart from each other. That is, in a plan view, the second wiring part ML1-2 may be apart from each of the transistor portion CCP and the plurality of sub-wiring portions MSL in the circuit arranging area CA. Accordingly, a phenomenon that electrical inferences occur between the first wiring portion ML1 and the plurality of sub-wiring portions MSL may be reduced. Also, a phenomenon that electrical inferences occur between the first wiring portion ML1 and the transistor portion CCP may be reduced.

In a cross-sectional view, the plurality of wiring portions ML, the plurality of sub-wiring portions MSL, and the transistor portion CCP may be located on different layers. As an example, in a cross-sectional view, the plurality of wiring portions ML may be located on the plurality of sub-wiring portions MSL, and the transistor portion CCP may be located on the plurality of wiring portions ML. However, this is just an example, and the arrangements of the plurality of wiring portions ML, the plurality of sub-wiring portions MSL, and the transistor portion CCP are not limited thereto.

The first inorganic encapsulation layer 410 of the encapsulation layer 400 may cover the display area DA, and extend to the non-display area NDA to cover at least a portion of the plurality of dams DAM.

As an example, the organic encapsulation layer 420 may be in contact with an inner surface of the plurality of dams DAM facing the display area DA. When the organic encapsulation layer 420 is in contact with the inner surface of the plurality of dams DAM, it may be understood that the first inorganic encapsulation layer 410 is located between the organic encapsulation layer 420 and the plurality of dams DAM, and the organic encapsulation layer 420 is in direct contact with the first inorganic encapsulation layer 410. The first inorganic encapsulation layer 410 and the second inorganic encapsulation layer 430 may be located on the plurality of dams DAM, and may extend to the edge of the substrate 100.

As an example, the organic encapsulation layer 420 may be in contact with an inner surface of the second dam 220 facing the display area DA. The organic encapsulation layer 420 overflowing to the outside of the second dam 220 by the second dam 220 may be prevented or reduced.

As an example, the organic encapsulation layer 420 of the encapsulation layer 400 may cover the display area DA, and extend to the non-display area NDA, and the area of the organic encapsulation layer 420 may be limited by another dam (e.g., the second dam 220) instead of a dam (e.g., the third dam 230) located in the outermost portion.

The second inorganic encapsulation layer 430 of the encapsulation layer 400 may cover the display area DA, and extend to the non-display area NDA to be in contact with the first inorganic encapsulation layer 410 outside the organic encapsulation layer 420. It is shown in FIG. 7 that the second inorganic encapsulation layer 430 extends to at least a portion of the dam (e.g., the third dam 230) located in the outermost portion.

A support SS may be located in the non-display area NDA. The support SS may be located outside the plurality of dams DAM. The support SS may be a member for supporting a mask that is used during a mask process. The support SS may have a single-layered structure or a multi-layered structure. In FIG. 7, the support SS is shown as a two-layered structure. The support SS may be located outside the plurality of dams DAM and may protrude above the substrate.

A lower layer SS1 of the support SS may include the same material as the organic insulating layer 104, and the lower layer SS1 of the support SS may be located on the same layer as the organic insulating layer 104. An upper layer SS2 of the support SS may include the same material as the pixel-defining layer 105, and the upper layer SS2 of the support SS may be located on the same layer as the pixel-defining layer 105. The inner surface of the support SS may be covered by the first inorganic encapsulation layer 410 and the second inorganic encapsulation layer 430. As an example, because an organic material is not located between the third dam 230 and the support SS, moisture transmission of external air may be effectively blocked.

FIG. 9 is a schematic equivalent circuit diagram of a pixel PX of the display device 1 of FIG. 1. Although FIG. 9 illustrates various components in a pixel according to some embodiments, embodiments according to the present disclosure are not limited thereto, and according to some embodiments, the pixels may include additional components without departing from the spirit and scope of embodiments according to the present disclosure.

As shown in FIG. 9, each pixel PX may include a pixel circuit PC and an organic light-emitting element OLED connected to the pixel circuit PC, wherein the pixel circuit PC is connected to the scan line SL and the data line DL.

As an example, the pixel circuit PC may include a driving thin-film transistor Td, a switching thin-film transistor Ts, and a storage capacitor Cst. The switching thin-film transistor Ts may be connected to the scan line SL and the data line DL, and configured to transfer a data signal Dm to the driving thin-film transistor Td according to a scan signal Sn, wherein the data signal Dm is input through the data line DL, and the scan signal Sn is input through the scan line SL.

Reference, a scan signal Sn may be a scan signal SC_N of FIGS. 4 and 6. A scan signal Sn may be a signal generated in the circuit diagram of FIG. 4 or the circuit diagram of FIG. 6. A scan signal Sn may be a signal generated by the scan driver GP of FIG. 2. A scan signal Sn may be a signal generated in the circuit diagram of FIG. 4 or the circuit diagram of FIG. 6 based on input signals generated by the controller CP of FIG. 2.

As an example, the storage capacitor Cst may be connected to the switching thin-film transistor Ts and the driving voltage line PL and configured to store a voltage corresponding to a difference between a voltage transferred from the switching thin-film transistor Ts and a first power voltage ELVDD (or a driving voltage) supplied to the driving voltage line PL.

As an example, the driving thin-film transistor Td may be connected to the driving voltage line PL and the storage capacitor Cst and configured to control a driving current according to the voltage stored in the storage capacitor Cst, the driving current flowing from the driving voltage line PL to the organic light-emitting element OLED. The organic light-emitting element OLED may be configured to emit light having a preset brightness corresponding to the driving current.

The organic light-emitting element OLED may receive a second power voltage ELVSS (or a common voltage). As an example, the organic light-emitting element OLED may receive the second power voltage ELVSS (or the common voltage) through the opposite electrode (a cathode) and emit light having a preset brightness based on the driving current corresponding to a voltage difference between the first power voltage ELVDD (or the driving voltage) and the second power voltage ELVSS (or the common voltage).

Although it is described with reference to FIG. 9 that the pixel circuit PC includes two thin-film transistors and one storage capacitor, the embodiments according to the present disclosure are not limited thereto. As an example, the pixel circuit PC may include not only two or more storage capacitors but also three or more thin-film transistors.

The display device according to some embodiments is applicable to various electronic devices. An electronic device according to some embodiments may include the display device described above and may further include a module or a device having another additional function in addition to the display device.

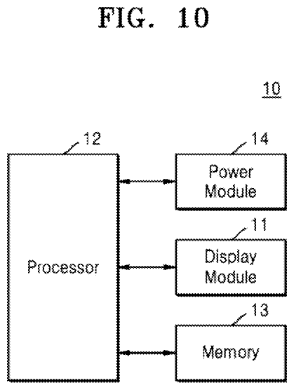

FIG. 10 is a block diagram of an electronic device 10 according to some embodiments.

Referring to FIG. 10, the electronic device 10 according to some embodiments may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), or a controller.

The memory 13 may store data information required for operations of the processor 12 or the display module 11. When the processor 12 executes an application stored in the memory 13, an image data signal and/or an input control signal may be transferred to the display module 11, and the display module 11 may process a provided signal and output image information through a display screen.

The power module 14 may include a power supply module such as a power adapter or a battery unit, and a power converting module converting power supplied by the power supply module and generating power required for operations of the electronic device 10.

At least one of elements of the electronic device 10 may be included in the display device according to the embodiments. In addition, some of individual modules functionally included in one module may be included in the display device, and some other may be provided separately from the display device. As an example, the display device may include the display module 11, and the processor 12, the memory 13, and the power module 14 may be provided in the form of another device within the electronic device 10 instead of the display device.

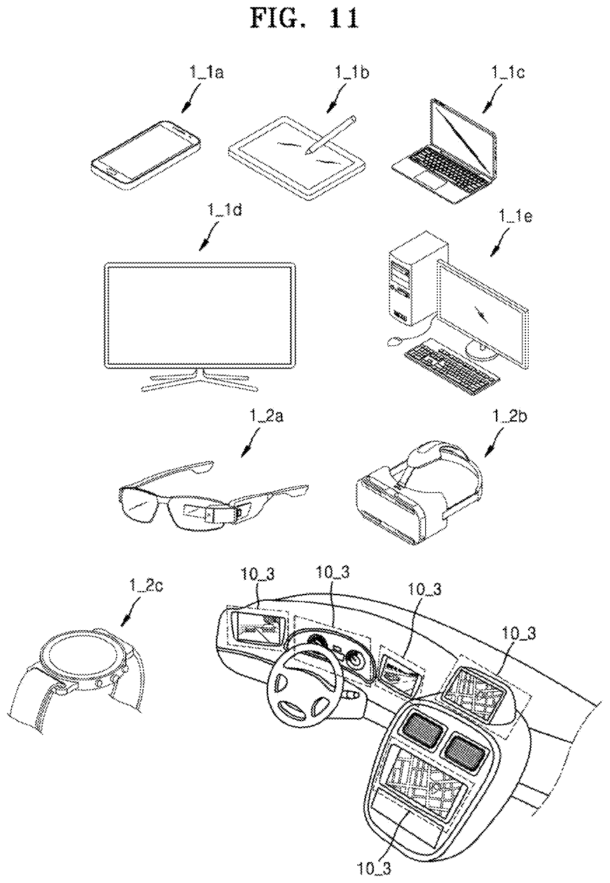

FIG. 11 is a schematic view of electronic devices according to various embodiments.

Referring to FIG. 11, the various electronic devices employing the display device according to the embodiments may include not only electronic devices for displaying images, such as a smartphone 10_1a, a tablet personal computer (PC) 10_1b, a laptop computer 10_1c, a TV 10_1d, and a desk monitor 10_1e, but also wearable electronic devices including a display module, such as a smart glasses 10_2a, a head mount display 10_2b, and a smart watch 10_2c, and vehicle electronic devices 10_3 including a display module, such as an instrument panel of an automobile, a center fascia, a center information display (CID) arranged on or in (or incorporated into) a dashboard, and a room mirror display.

While aspects of some embodiments of the present invention have been described with reference to some embodiments as shown in the drawings, it will be understood by those of ordinary knowledge in the art that these are mere examples and various changes and modifications of the embodiments may be made therefrom. Accordingly, the true technical scope of embodiments according to the present invention should be defined by the spirit of the appended claims, and their equivalents.

According to some embodiments, the durability and the quality of the display device may be relatively improved.

Aspects of embodiments according to the present disclosure are not limited to the above mentioned characteristics and other characteristics not mentioned may be more clearly understood by those of ordinary skill in the art from the following claims.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims, and their equivalents.

What is claimed is:

1. A display device including a wiring arranging area, a circuit arranging area, and a display area sequentially arranged in a first direction, the display device comprising:
a substrate;
a pixel circuit on the substrate and located in the display area;
a transistor portion on the substrate, located in the circuit arranging area, and including at least one transistor;
a plurality of dams on the substrate, in the wiring arranging area, spaced apart from each other in the first direction, and including a first dam in an innermost side;
a plurality of wiring portions between the substrate and the plurality of dams in a cross-sectional view, spaced apart from each other in the first direction, and including a first wiring portion in the innermost side; and
an encapsulation layer on the substrate, including an organic encapsulation layer, and covering the display area and the circuit arranging area,
wherein the first wiring portion includes:
a first wiring part extending in a second direction crossing the first direction and located in the wiring arranging area; and
a second wiring part extending in the first direction from the first wiring part and having at least a portion located in the circuit arranging area.

2. The display device of claim 1, wherein, in a plan view, the organic encapsulation layer overlaps the first dam.

3. The display device of claim 1, wherein, in a plan view, the first wiring part is outside the first dam.

4. The display device of claim 1, wherein, in a plan view, the second wiring part overlaps the first dam.

5. The display device of claim 1, wherein, in a plan view, an end of the second wiring part is inside the first dam.

6. The display device of claim 1, wherein the second wiring part is provided in plurality.

7. The display device of claim 1, wherein, in a plan view, the transistor portion and the second wiring part are spaced apart from each other.

8. The display device of claim 1, wherein the pixel circuit includes:
a semiconductor layer;
a gate layer overlapping the semiconductor layer;
a source electrode electrically connected to a source region of the semiconductor layer; and
a drain electrode electrically connected to a drain region of the semiconductor layer,
wherein the first wiring portion, the source electrode, and the drain electrode are on a same layer and include a same material.

9. The display device of claim 1, further comprising a plurality of sub-wiring portions extending in the first direction, located in the wiring arranging area and the circuit arranging area, and electrically connecting the plurality of wiring portions and the transistor portion to each other.

10. The display device of claim 9, wherein, in a plan view, the second wiring part is spaced apart from each of the transistor portion and the plurality of sub-wiring portions.

11. An electronic device including a display device including a wiring arranging area, a circuit arranging area, and a display area sequentially arranged in an inner direction, the electronic device comprising:
a substrate;
a pixel circuit on the substrate and located in the display area;
a transistor portion on the substrate, located in the circuit arranging area, and including at least one transistor;
a plurality of dams on the substrate, located in the wiring arranging area, spaced apart from each other in the inner direction, and including a first dam in an innermost side;
a plurality of wiring portions between the substrate and the plurality of dams in a cross-sectional view, spaced apart from each other in the inner direction, and including a first wiring portion in the innermost side; and
an encapsulation layer on the substrate, including an organic encapsulation layer, and covering the display area and the circuit arranging area,
wherein the first wiring portion includes:
a first wiring part extending in a circumferential direction of the substrate and located in the wiring arranging area; and
a second wiring part extending in the inner direction from the first wiring part and having at least a portion in the circuit arranging area.

12. The electronic device of claim 11, wherein, in a plan view, the organic encapsulation layer overlaps the first dam.

13. The electronic device of claim 11, wherein, in a plan view, the first wiring part is outside the first dam.

14. The electronic device of claim 11, wherein, in a plan view, the second wiring part overlaps the first dam.

15. The electronic device of claim 11, wherein, in a plan view, an end of the second wiring part is inside the first dam.

16. The electronic device of claim 11, wherein the second wiring part is provided in plurality.

17. The electronic device of claim 11, wherein, in a plan view, the transistor portion and the second wiring part are spaced apart from each other.

18. The electronic device of claim 11, wherein the pixel circuit includes:
a semiconductor layer;
a gate layer on the semiconductor layer;
a source electrode electrically connected to a source region of the semiconductor layer; and
a drain electrode electrically connected to a drain region of the semiconductor layer,
wherein the first wiring portion, the source electrode, and the drain electrode are on a same layer and include a same material.

19. The electronic device of claim 11, further comprising a plurality of sub-wiring portions extending in the inner direction, located in the wiring arranging area and the circuit arranging area, and electrically connecting the plurality of wiring portions and the transistor portion to each other.

20. The electronic device of claim 19, wherein, in a plan view, the second wiring part is spaced apart from each of the transistor portion and the plurality of sub-wiring portions.
